(19) United States
(12) Patent Application Publication
(10) Pub. No.: US 2026/0047374 A1
(43) Pub. Date: Feb. 12, 2026

(54) METHOD FOR MANUFACTURING SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventor: Kenichi OOHASHI, Kawasaki Kanagawa (JP)

(21) Appl. No.: 19/360,846

(22) Filed: Oct. 16, 2025

Related U.S. Application Data
(63) Continuation of application No. PCT/JP2024/013403, filed on Apr. 1, 2024.

(30) Foreign Application Priority Data
Jul. 31, 2023 (JP) 2023-124034

(51) Int. Cl. H01L 21/78

(52) U.S. Cl. CPC H01L 21/78

(57) ABSTRACT

A method for manufacturing a semiconductor device of an embodiment includes a first film forming step of forming a first electrode layer on a base material back surface facing a side opposite to a device surface of a base material on which a circuit portion is formed. The method includes a second film forming step of forming a second electrode layer on a front surface of a film-formed member. The method includes a joining step of joining the first electrode layer and the second electrode layer. The method includes a film-formed member removing step of removing the film-formed member from the second electrode layer.

### CROSS-REFERENCE TO RELATED APPLICATION

This application is based upon and claims the benefit of priority from Japanese Patent Application No. 2023-124034, filed on Jul. 31, 2023, the contents of which are incorporated herein by reference.

### FIELD

Embodiments described herein relate generally to a method for manufacturing a semiconductor device.

### BACKGROUND

In a semiconductor device, the thickness of a base material may be reduced in order to improve the characteristics of the semiconductor device. In addition, in the semiconductor device, the heating value generated by a circuit portion formed on the base material is likely to become large. For these reasons, the temperature of the semiconductor device is likely to become high, and when the temperature of the semiconductor device becomes too high, there is a risk that the operation of the semiconductor device will become unstable.

### BRIEF DESCRIPTION OF THE DRAWINGS

FIG. 1 is a schematic cross-sectional view showing a semiconductor device according to a first embodiment.

FIG. 2 is a flowchart showing a method for manufacturing a semiconductor device according to the first embodiment.

FIG. 3 is a schematic cross-sectional view showing a device surface forming step according to the first embodiment.

FIG. 4 is a schematic cross-sectional view showing a first attaching step according to the first embodiment.

FIG. 5 is a schematic cross-sectional view showing a first film forming step according to the first embodiment.

FIG. 6 is a schematic cross-sectional view showing a second film forming step according to the first embodiment.

FIG. 7 is a schematic cross-sectional view showing a joining step according to the first embodiment.

FIG. 8 is a schematic cross-sectional view showing a film-formed member removing step according to the first embodiment.

FIG. 9 is a schematic cross-sectional view showing a second attaching step according to the first embodiment.

FIG. 10 is a first schematic cross-sectional view showing a support substrate removing step according to the first embodiment.

FIG. 11 is a second schematic cross-sectional view showing a support substrate removing step according to the first embodiment.

FIG. 12 is a first schematic cross-sectional view showing a dicing step according to the first embodiment.

FIG. 13 is a second schematic cross-sectional view showing a dicing step according to the first embodiment.

FIG. 14 is a flowchart showing a method for manufacturing a semiconductor device according to a second embodiment.

FIG. 15 is a schematic cross-sectional view showing a second film forming step according to the second embodiment.

FIG. 16 is a schematic cross-sectional view showing a film-formed member removing step according to the second embodiment.

### DETAILED DESCRIPTION

A method for manufacturing a semiconductor device of an embodiment includes a first film forming step of forming a first electrode layer on a base material back surface facing a side opposite to a device surface of a base material on which a circuit portion is formed. The method includes a second film forming step of forming a second electrode layer on a front surface of a film-formed member. The method includes a joining step of joining the first electrode layer and the second electrode layer. The method includes a film-formed member removing step of removing the film-formed member from the second electrode layer.

Hereinafter, a method for manufacturing a semiconductor device of embodiments will be described with reference to the drawings.

In the following description, in order to indicate the positional relationships of members, layers, and the like that constitute the semiconductor device, the upper side of each drawing will be referred to as the “upper side,” the lower side of each drawing will be referred to as the “lower side,” and the vertical direction of each drawing will be referred to as the “vertical direction.” The terms “upper side,” “lower side,” and “vertical direction” do not indicate a relationship with the direction of gravity. In the following description, among the outer surfaces of the members, the layers, and the like that constitute the semiconductor device, a surface facing upward will be referred to as a front surface, and a surface facing downward will be referred to as a back surface.

### First Embodiment

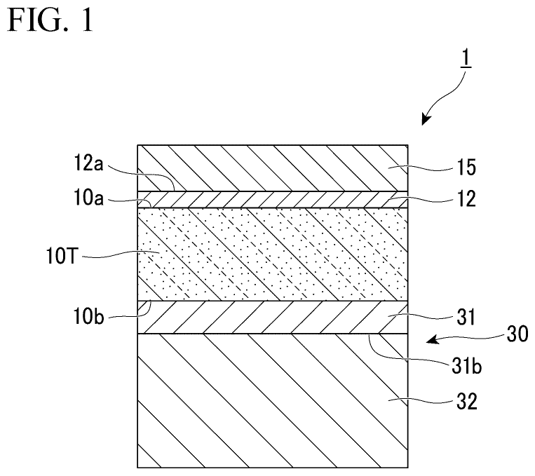

FIG. 1 is a schematic cross-sectional view of a semiconductor device 1 according to the present embodiment. The semiconductor device 1 of the present embodiment is, for example, a semiconductor device such as a MOSFET or an insulated gate bipolar transistor (IGBT). The semiconductor device 1 of the present embodiment includes a rectangular plate-shaped semiconductor chip 10T, a circuit portion 12, a front surface electrode portion 15, and a back surface electrode portion 30.

The semiconductor chip 10T is made of a semiconductor material. In the present embodiment, as the semiconductor material constituting the semiconductor chip 10T, for example, silicon (Si), silicon carbide (SiC), gallium arsenide (GaAs), gallium nitride (GaN), or the like can be used, but the semiconductor material is not limited to these.

The circuit portion 12 is formed on a device surface 10a, which is a front surface of the semiconductor chip 10T. The circuit portion 12 is constituted by, for example, a plurality of devices such as semiconductor elements constituting a MOSFET, a circuit pattern that electrically connects the devices, and the like.

The front surface electrode portion 15 is formed on a front surface 12a of the circuit portion 12. For example, in a case in which the semiconductor device 1 is a MOSFET, the front surface electrode portion 15 includes a gate electrode and a source electrode of the MOSFET. The front surface electrode portion 15 contains a material having electrical conductivity. As the material constituting the front surface electrode portion 15, for example, metals such as copper, aluminum, nickel, silver, and gold, alloys containing at least one of these metals, and the like can be used, but the material constituting the front surface electrode portion 15 is not limited to these.

The back surface electrode portion 30 is formed on a base material back surface 10b, which is a back surface of the semiconductor chip 10T. For example, in a case in which the semiconductor device 1 is a MOSFET, the back surface electrode portion 30 is a drain electrode of the MOSFET. The back surface electrode portion 30 contains a material having electrical conductivity. As the material constituting the back surface electrode portion 30, for example, metals such as copper, aluminum, nickel, silver, and gold, alloys containing at least one of these metals, and the like can be used, but the material constituting the back surface electrode portion 30 is not limited to these. In the present embodiment, the back surface electrode portion 30 is made of copper. The back surface electrode portion 30 has a first electrode layer 31 and a second electrode layer 32.

The first electrode layer 31 is formed on the base material back surface 10b of the semiconductor chip 10T. In the present embodiment, the first electrode layer 31 is made of copper. The second electrode layer 32 is formed on a back surface 31b of the first electrode layer 31. The second electrode layer 32 is joined to the first electrode layer 31. In the present embodiment, the second electrode layer 32 is made of copper. The thickness of the second electrode layer 32 is greater than the thickness of the first electrode layer 31. In the present embodiment, the thickness of the second electrode layer 32 is preferably in the range of 10 μm or more and 50 μm or less. In the present embodiment, the thickness of the second electrode layer 32 is about 20 μm. The thickness of the second electrode layer 32 may be less than 10 μm or may be more than 50 μm.

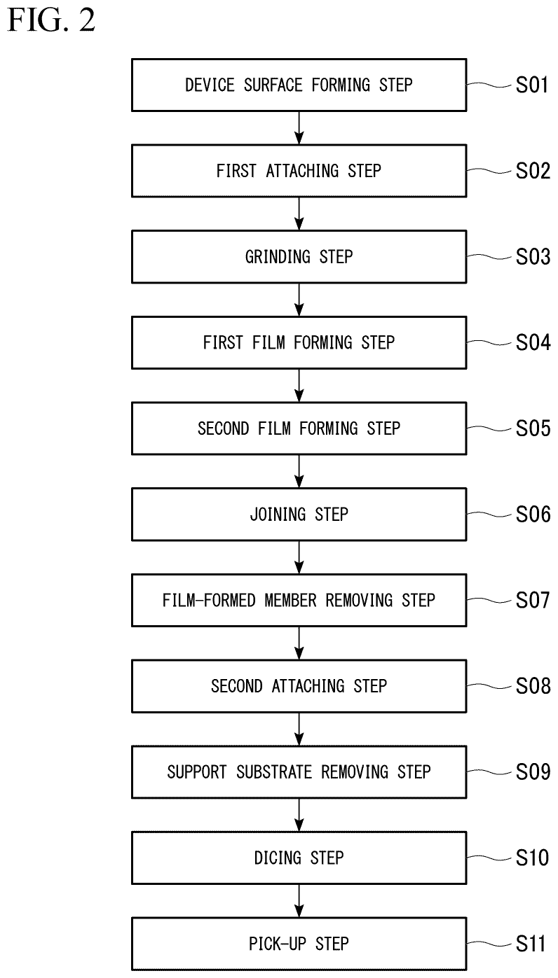

FIG. 2 is a flowchart showing a method for manufacturing the semiconductor device 1 according to the present embodiment. The method for manufacturing the semiconductor device 1 of the present embodiment has a device surface forming step S01, a first attaching step S02, a grinding step S03, a first film forming step S04, a second film forming step S05, a joining step S06, a film-formed member removing step

S07, a second attaching step S08, a support substrate removing step S09, a dicing step S10, and a pick-up step S11. In the following description, the term “operator or the like” includes an operator who performs an operation in each step, an assembly apparatus, or the like. The operation in each step may be performed by the operator alone, may be performed by the assembly apparatus alone, or may be performed by the operator and the assembly apparatus.

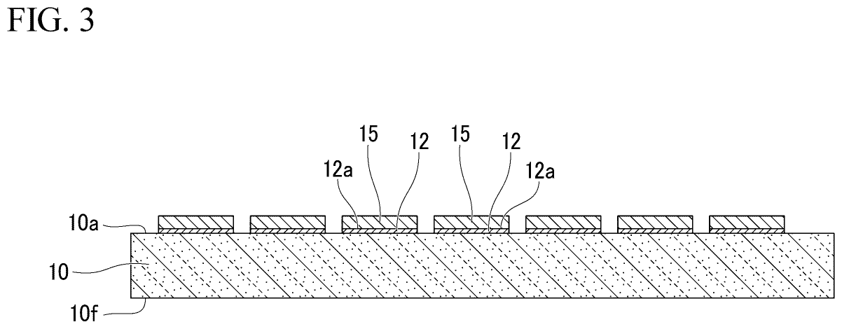

As shown in FIG. 3, the device surface forming step S01 is a step of forming the circuit portion 12 and the front surface electrode portion 15 on the device surface 10a of a base material 10. First, the operator or the like forms a plurality of circuit portions 12 on the device surface 10a, which is a front surface of the disk-shaped base material 10 (a semiconductor wafer) made of a semiconductor material. The device surface 10a is a surface of the base material 10 which faces the upper side. The circuit portions 12 are formed at intervals from each other. The plurality of circuit portions 12 are formed side by side in a left-right direction of FIG. 3. In addition, although not shown, the plurality of circuit portions 12 may be formed side by side in a direction perpendicular to a paper surface of FIG. 3. In this case, the circuit portions 12 are disposed side by side in the left-right direction of FIG. 3 and in the direction perpendicular to the paper surface of FIG. 3. In the following description, in the steps prior to the grinding step S03, a surface of the base material 10 which faces a side opposite to the device surface 10a is an initial back surface 10f.

Next, the operator or the like forms the front surface electrode portion 15 on the front surface 12a of each of the circuit portions 12. In the present embodiment, the front surface electrode portion 15 is formed by a physical vapor deposition method such as sputtering. When the front surface electrode portion 15 is formed on the front surface 12a of each of the circuit portions 12, the device surface forming step S01 is completed.

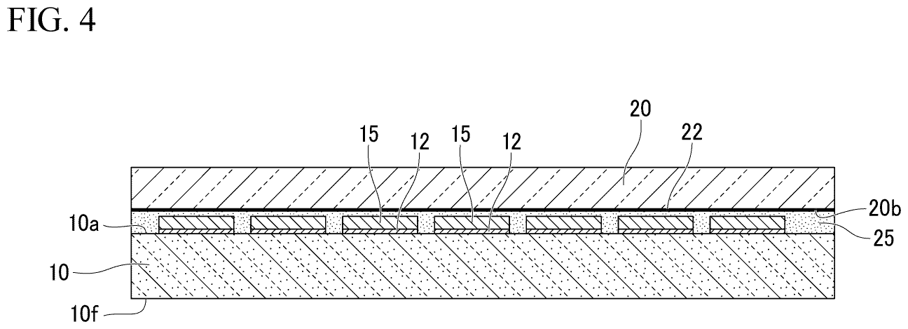

As shown in FIG. 4, the first attaching step S02 is a step of attaching a support substrate 20 to the device surface 10a of the base material 10 with an adhesive 25. The first attaching step S02 is a step prior to the first film forming step S04. First, the operator or the like applies an uncured adhesive 25 to the device surface 10a. The adhesive 25 is applied to a front surface of each of the front surface electrode portions 15, between the front surface electrode portions 15, and also between the circuit portions 12. As the adhesive 25, for example, an acrylic adhesive, an epoxy adhesive, and a silicon adhesive can be used.

Next, the operator or the like attaches the device surface 10a of the base material 10 and a back surface 20b of the support substrate 20 to each other with the adhesive 25 interposed therebetween. In the present embodiment, the support substrate 20 is a plate-shaped member made of, for example, glass and silicon. In the present embodiment, the support substrate 20 has a light transmitting property. A release layer 22 is formed on the back surface 20b of the support substrate 20. In the present embodiment, the release layer 22 contains carbon. The release layer 22 is black in color. Next, the operator or the like cures the adhesive 25 and attaches the support substrate 20 to the device surface 10a. As a result, the base material 10 is supported by the support substrate 20. When the support substrate 20 is attached to the device surface 10a, the first attaching step S02 is completed.

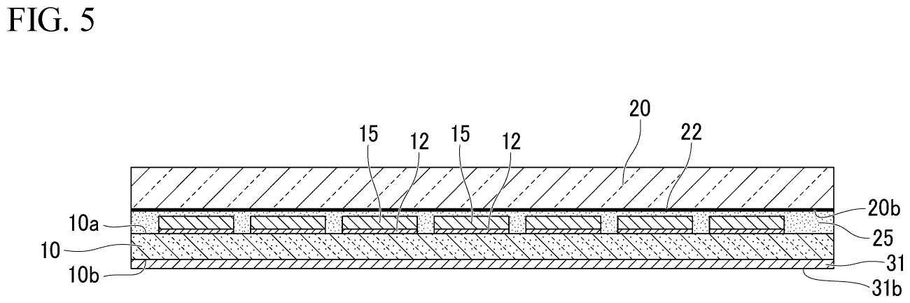

As shown in FIG. 5, the grinding step S03 is a step of grinding a lower portion of the base material 10 to reduce the thickness of the base material 10 and form the base material back surface 10b. In a state in which the base material 10 is supported by the support substrate 20, the operator or the like grinds the lower portion of the base material 10. When the lower portion of the base material 10 is ground, the base material 10 becomes thinner. That is, in the grinding step S03, the base material 10 is thinned. In addition, the lower portion of the base material 10 is ground, and thus the base material back surface 10b of the base material 10 is formed. The base material back surface 10b is a surface of the base material 10 which faces the lower side. The base material back surface 10b is a surface facing a side opposite to the device surface 10a. When the base material back surface 10b is formed, the grinding step S03 is completed.

The first film forming step S04 is a step of forming the first electrode layer 31 on the base material back surface 10b of the base material 10. The first film forming step S04 is performed in a state in which the base material 10 is supported by the support substrate 20. In the present embodiment, the first electrode layer 31 is formed by a physical vapor deposition method. More specifically, the first electrode layer 31 is formed by sputtering. The first electrode layer 31 may be formed by another physical vapor deposition method such as a heating deposition method or may be formed by a chemical vapor deposition method. As described above, in the present embodiment, the first electrode layer 31 is made of copper. The first electrode layer 31 is formed with a uniform thickness over the entire base material back surface 10b. The thickness of the first electrode layer 31 is, for example, about 1 μm. The thickness of the first electrode layer 31 may be less than 1 μm or may be more than 1 μm. When the first electrode layer 31 is formed on the base material back surface 10b, the first film forming step S04 is completed. Although not shown in the drawings, in the present embodiment, the first electrode layer 31 is formed on the base material back surface 10b with a stacked film constituted by, for example, titanium (Ti) and copper. As a result, it is possible to prevent the copper constituting the first electrode layer 31 from diffusing into the base material 10.

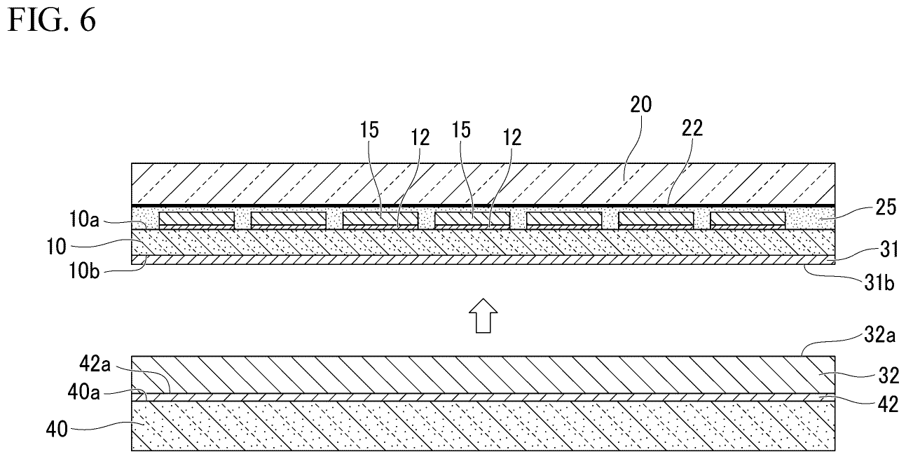

As shown in FIG. 6, the second film forming step S05 is a step of forming the second electrode layer 32 on a front surface 40a of a film-formed member 40. In the present embodiment, the film-formed member 40 is made of a semiconductor material. As the semiconductor material constituting the film-formed member 40, for example, silicon, silicon carbide, gallium arsenide, gallium nitride, or the like can be used, but the semiconductor material is not limited to these. The film-formed member 40 may be constituted by another material such as a metal. In the present embodiment, the film-formed member 40 has a disk shape. The film-formed member 40 may have another shape such as a cylindrical shape. In the second film forming step S05, first, the operator or the like forms an intermediate layer 42 on the front surface 40a of the film-formed member 40. The intermediate layer 42 is constituted by aluminum or a material containing aluminum atoms, such as alumina (Al₂O₃). In the present embodiment, the intermediate layer 42 is constituted by alumina.

Next, the operator or the like forms the second electrode layer 32 on a front surface 42a of the intermediate layer 42. In the second film forming step S05, the second electrode layer 32 is formed on the front surface 40a of the film-formed member 40 with the intermediate layer 42 interposed therebetween. In the present embodiment, the second electrode layer 32 is formed by a plating process. More specifically, a stacked film (not shown) constituted by titanium and copper is formed as a seed layer on the front surface 42a of the intermediate layer 42 by sputtering, and then the second electrode layer 32 is formed on the stacked film. After the film-formed member 40 is removed from the second electrode layer 32 in the film-formed member removing step S07, the stacked film may be removed as necessary to expose the second electrode layer 32. The thickness of the second electrode layer 32 is preferably in the range of 10 μm or more and 50 μm or less. In the present embodiment, the thickness of the second electrode layer 32 is about 20 μm. The thickness of the second electrode layer 32 is greater than the thickness of the first electrode layer 31. As described above, in the present embodiment, the second electrode layer 32 is made of copper. Therefore, a material constituting the first electrode layer 31 and a material constituting the second electrode layer 32 are the same material. When the second electrode layer 32 is formed on the front surface 40a of the film-formed member 40, the second film forming step S05 is completed.

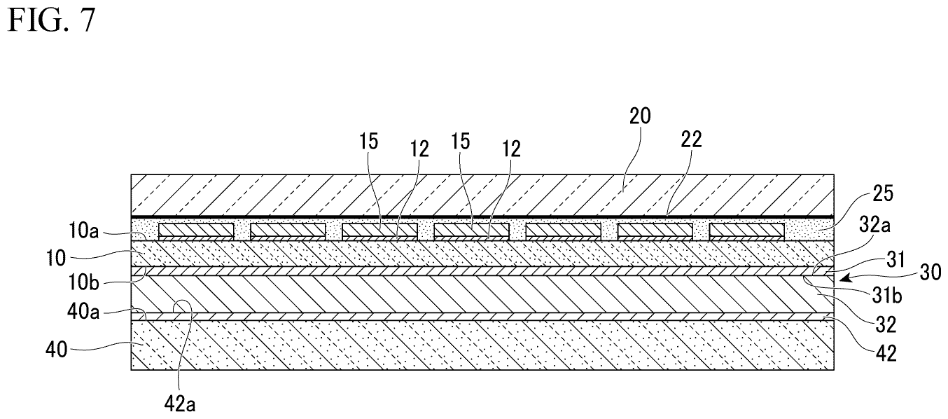

The joining step S06 is a step of joining the first electrode layer 31 and the second electrode layer 32 to form the back surface electrode portion 30. The joining step S06 is performed in a vacuum inside a chamber (not shown). As shown in FIG. 6, the operator or the like moves the film-formed member 40 with the front surface 40a facing the upper side from the lower side to the upper side of the base material 10 and presses the film-formed member 40 against the base material 10. As a result, a front surface 32a of the second electrode layer 32 is pressed against the back surface 31b of the first electrode layer 31, as shown in FIG. 7. Next, the operator or the like heats at least one of the first electrode layer 31 and the second electrode layer 32 while pressing the front surface 32a of the second electrode layer 32 against the back surface 31b of the first electrode layer 31. As a result, the front surface 32a of the second electrode layer 32 and the back surface 31b of the first electrode layer 31 are joined to each other. That is, the first electrode layer 31 and the second electrode layer 32 are joined to each other. When the first electrode layer 31 and the second electrode layer 32 are joined to each other, the back surface electrode portion 30 is formed. When the back surface electrode portion 30 is formed, the joining step S06 is completed.

According to the present embodiment, as shown in FIG. 2, the method for manufacturing the semiconductor device 1 has the first attaching step S02 of attaching the support substrate 20 to the device surface 10a of the base material 10 with the adhesive 25 prior to the first film forming step S04. Therefore, it is possible to stably support the base material 10 thinned in the grinding step S03 by the support substrate 20. For this reason, in the first film forming step S04, it is possible to prevent the thinned base material 10 from being deformed in the vertical direction. Therefore, in the first film forming step S04, it is possible to increase the uniformity of the thickness of the first electrode layer 31 formed on the base material back surface 10b, and thus it is possible to suppress variation in the joining strength between the first electrode layer 31 and the second electrode layer 32. As a result, it is possible to increase the strength of the back surface electrode portion 30.

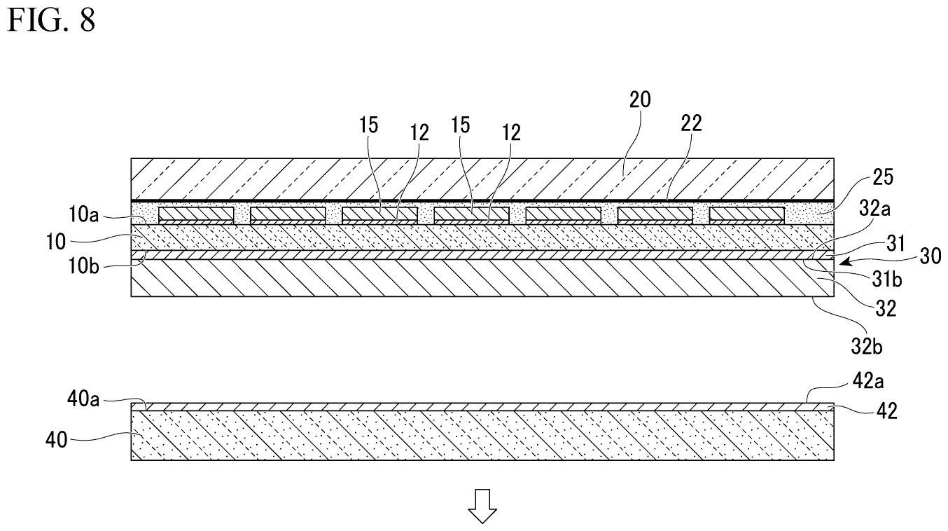

As shown in FIG. 8, the film-formed member removing step S07 is a step of removing the film-formed member 40 from the second electrode layer 32. First, the operator or the like immerses at least the intermediate layer 42 in water stored in a bath (not shown). When the intermediate layer 42 is immersed in the water, the water permeates an interface between the intermediate layer 42 and the second electrode layer 32. As a result, it is possible to reduce the joining strength between the intermediate layer 42 and the second electrode layer 32. This is considered to be due to the following phenomenon. First, the intermediate layer 42 containing the aluminum atoms undergoes a hydration reaction with the permeated water, and thus alumina hydrate crystals grow on the front surface 42a of the intermediate layer 42. For this reason, the surface roughness of the surface 42a of the intermediate layer 42 increases, and thus the contact area between the front surface 42a of the intermediate layer 42 and a back surface 32b of the second electrode layer 32 decreases. As a result, the joining strength between the intermediate layer 42 and the second electrode layer 32 is reduced. The intermediate layer 42 and the film-formed member 40 may be immersed in the water, or in addition to the intermediate layer 42 and the film-formed member 40, a portion from the support substrate 20 to the second electrode layer 32 may also be immersed in the water.

Next, the operator or the like holds the support substrate 20 with one jig or the like (not shown) while holding the film-formed member 40 with the other jig or the like (not shown) and moves the other jig to the lower side relative to the one jig. As described above, the joining strength between the intermediate layer 42 and the second electrode layer 32 is reduced, and thus it is possible to peel off the intermediate layer 42 from the second electrode layer 32 by moving the other jig to the lower side relative to the one jig. As a result, the operator or the like can remove the intermediate layer 42 and the film-formed member 40 from the second electrode layer 32. That is, in the film-formed member removing step S07, after at least the intermediate layer 42 is immersed in the water, the film-formed member 40 is removed from the second electrode layer 32.

According to the present embodiment, in the film-formed member removing step S07, as described above, it is possible to reduce the joining strength between the intermediate layer 42 and the second electrode layer 32 by immersing the intermediate layer 42 in the water, and thus it is possible to easily peel off the intermediate layer 42 from the second electrode layer 32. As a result, it is possible to easily remove the film-formed member 40 from the second electrode layer 32. For example, in the case in which a mixed acid solution of nitric acid, hydrofluoric acid, and the like is penetrated into the intermediate layer 42 to deteriorate the intermediate layer 42 and reduce the joining strength between the intermediate layer 42 and the second electrode layer 32, when such a mixed acid solution adheres to the adhesive 25, there is a risk that the adhesive 25 will be deteriorated. For this reason, there is a risk that the adhesive strength between the support substrate 20 and the base material 10 will decrease. On the other hand, in the present embodiment, the joining strength between the intermediate layer 42 and the second electrode layer 32 is reduced with water, and thus even when the water adheres to the adhesive 25, the adhesive 25 is not deteriorated. Therefore, in the present embodiment, it is possible to suppress a decrease in the adhesive strength between the support substrate 20 and the base material 10.

In addition, according to the present embodiment, as described above, the joining strength between the intermediate layer 42 and the second electrode layer 32 is reduced with the water without using, for example, the mixed acid solution of nitric acid, hydrofluoric acid, and the like. Accordingly, it is possible to prevent the mixed acid solution from adhering to the circuit portion 12 and the front surface electrode portion 15, and thus it is possible to prevent the circuit portion 12 and the surface electrode portion 15 from being deteriorated. Therefore, it is possible to suppress a decrease in the yield of the semiconductor device 1, and it is possible to improve the stability of the operation of the semiconductor device 1.

In the present embodiment, the water is warm water. In the present embodiment, the temperature of the water is 50° C. or higher and 100° C. or lower. Therefore, according to the present embodiment, it is possible to suitably promote the reaction between the intermediate layer 42 and the water. Therefore, it is possible to stably reduce the joining strength between the intermediate layer 42 and the second electrode layer 32, and thus it is possible to easily remove the film-formed member 40 from the second electrode layer 32. The temperature of the water is preferably high, and the temperature of the water is preferably close to 100° C. When the film-formed member 40 is removed from the second electrode layer 32, the film-formed member removing step S07 is completed. In the film-formed member removing step S07, the method for removing the film-formed member 40 from the second electrode layer 32 is not limited to the method of the present embodiment. For example, the film-formed member 40 may be removed from the second electrode layer 32 by grinding the film-formed member 40 using a grinding process. In this case, the intermediate layer 42 may be removed from the second electrode layer 32 by grinding the intermediate layer 42 using the grinding process.

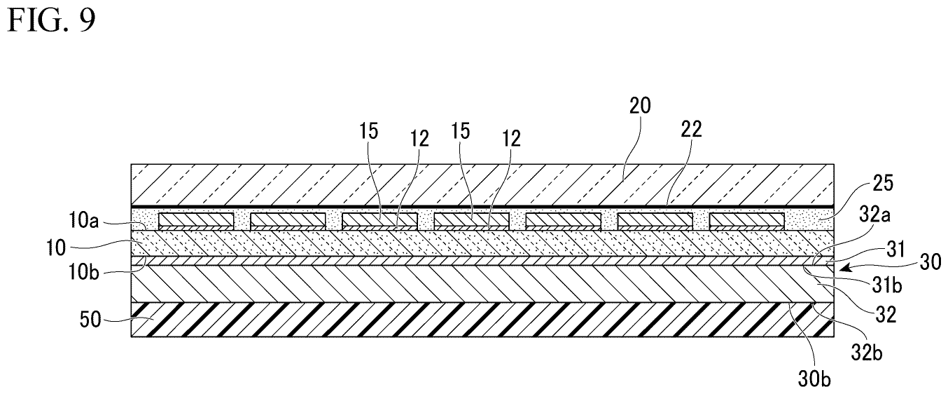

As shown in FIG. 9, the second attaching step S08 is a step of attaching a dicing tape 50 to the back surface 32b of the second electrode layer 32. In the dicing step S10 which will be described below, when the base material 10 is individualized, the dicing tape 50 fixes the individualized semiconductor chips 10T. The dicing tape 50 is attached to the back surface 32b of the second electrode layer 32. That is, the dicing tape 50 is attached to the back surface 30b of the back surface electrode portion 30. When the operator or the like attaches the dicing tape 50 to the back surface 32b of the second electrode layer 32, the second attaching step S08 is completed.

According to the present embodiment, as described above, in the film-formed member removing step S07, it is possible to reduce the joining strength between the intermediate layer 42 and the second electrode layer 32 with the water, and thus it is possible to suppress a deterioration of the adhesive 25. As a result, it is possible to suppress a decrease in the adhesive strength between the support substrate 20 and the base material 10. Therefore, in the second attaching step S08, it is possible to stably support the base material 10 by the support substrate 20, and thus it is possible to easily attach the dicing tape 50 to the back surface 30b of the back surface electrode portion 30. Accordingly, it is possible to suppress an increase in the amount of the operation required for the second attaching step S08.

According to the present embodiment, as shown in FIG. 2, the method for manufacturing the semiconductor device 1 has the first attaching step S02 of attaching the support substrate 20 to the device surface 10a of the base material 10 with the adhesive 25 prior to the first film forming step S04. Therefore, it is possible to stably support the base material 10 thinned in the grinding step S03 by the support substrate 20. For this reason, in each of the joining step S06, the film-formed member removing step S07, and the second attaching step S08, which are the steps subsequent to the first film forming step S04, it is possible to stabilize the shape of the base material 10 in the vertical direction and the position of the base material 10 in the vertical direction. Therefore, in the joining step S06, it is possible to easily join the first electrode layer 31 and the second electrode layer 32 to each other. In addition, in the film-formed member removing step S07, it is possible to easily remove the film-formed member 40 from the second electrode layer 32. Further, in the second attaching step S08, it is possible to easily attach the dicing tape 50 to the back surface 30b of the back surface electrode portion 30. Therefore, it is possible to simplify the operation in each of the joining step S06, the film-formed member removing step S07, and the second attaching step S08, and thus it is possible to suppress an increase in the number of steps required for manufacturing the semiconductor substrate 1.

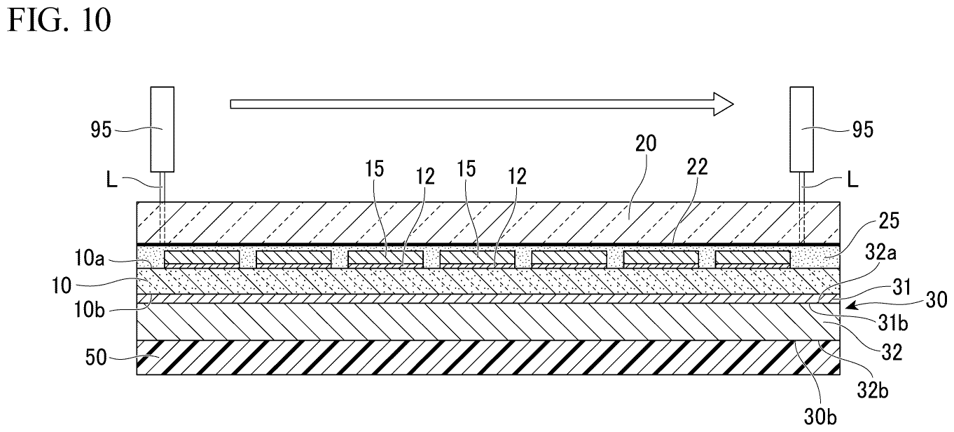

The support substrate removing step S09 is a step of removing the support substrate 20 from the base material 10. As shown in FIG. 2, the support substrate removing step S09 is a step performed after the film-formed member removing step S07. As shown in FIG. 10, first, the operator or the like irradiates the support substrate 20 with a laser beam L while a laser 95 disposed above the support substrate 20 is caused to perform scanning. As described above, since the support substrate 20 has a light transmitting property, the laser beam L passes through the inside of the support substrate 20 and is applied to the release layer 22. As described above, since the release layer 22 is black in color, the release layer 22 absorbs the laser beam L. As a result, the temperature of the release layer 22 increases, and thus the release layer 22 is separated from the support substrate 20. Thereafter, the adhesive 25 may be removed by being peeled off with an adhesive tape or may be removed by being dissolved with a solvent.

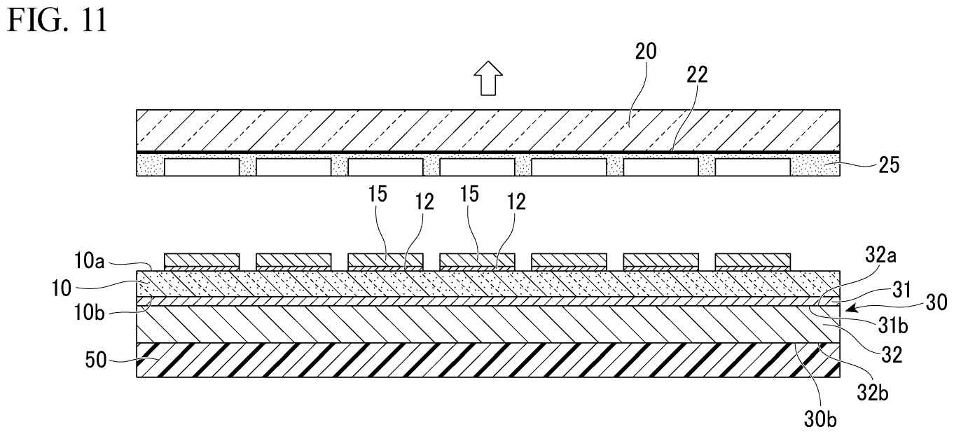

Next, as shown in FIG. 11, the operator or the like holds the support substrate 20 with one jig or the like (not shown) while holding the dicing tape 50 with the other jig or the like (not shown) and moves the one jig to the upper side relative to the other jig. As described above, since the adhesive strength between the adhesive 25 and each of the base material 10 and the front surface electrode portion 15 is reduced, it is possible to easily peel off the adhesive 25 from each of the base material 10 and the front surface electrode portion 15 by moving the one jig to the upper side relative to the other jig. As a result, the operator or the like can easily remove the support substrate 20 and the adhesive 25 from the base material 10.

In the support substrate removing step S09, a solvent may be penetrated into the adhesive 25 to deteriorate the adhesive 25 and reduce the adhesive strength between the adhesive 25 and each of the base material 10 and the front surface electrode portion 15, and then the support substrate 20 may be removed from the base material 10. In addition, the support substrate 20 may also be removed from the base material 10 by inserting a sharp tool between the base material 10 and the support substrate 20 and peeling off the adhesive 25 from the base material 10. In addition, in the support substrate removing step S09, it is preferable to remove any adhesive 25 remaining on the device surface 10a and the front surface electrode portion 15 by adhering a tape (not shown) to the device surface 10a and the front surface electrode portion 15 and then peeling off the tape after the support substrate 20 is removed from the base material 10. As a result, it is possible to perform stable electrical connection between the front surface electrode portion 15 and an external electrode (not shown) that is connected to the front surface electrode portion 15 when the semiconductor device 1 is in use, for example. Therefore, it is possible to improve the stability of the operation of the semiconductor device 1.

According to the present embodiment, the method for manufacturing the semiconductor device 1 has the support substrate removing step S09 for removing the support substrate 20 from the base material 10 after the film-formed member removing step S07. Therefore, in the film-formed member removing step S07, it is possible to support the base material 10 by the support substrate 20, and thus as described above, it is possible to easily peel off the intermediate layer 42 from the second electrode layer 32 by moving the film-formed member 40 to the lower side with the other jig or the like while holding the support substrate 20 with the one jig or the like. As a result, it is possible to simplify the operation of removing the film-formed member 40 from the second electrode layer 32, and thus it is possible to suppress an increase in the amount of the operation required for the film-formed member removing step S07.

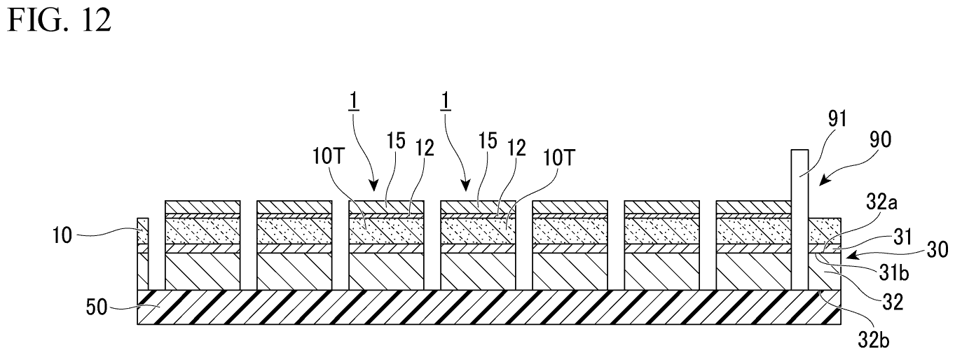

As shown in FIG. 12, the dicing step S10 is a step of separating the base material 10. The operator or the like cuts the base material 10 and the back surface electrode portion 30 to separate the base material 10 and divide the base material 10 into a plurality of semiconductor chips 10T. In the present embodiment, the operator or the like cuts the base material 10 and the back surface electrode portion 30 using a dicing device 90 having a blade 91. At this time, the circuit portion 12 and the front surface electrode portion 15 are formed on the device surface 10a of each semiconductor chip 10T. In addition, the back surface electrode portion 30 is formed on the base material back surface 10b of each semiconductor chip 10T. Therefore, when the base material 10 is separated, a plurality of semiconductor devices 1 (see FIG. 1) are formed. In addition, in the dicing step S10, the dicing tape 50 is not cut. Therefore, the semiconductor devices 1 are fixed by the dicing tape 50. The cutting of the base material 10 and the back surface electrode portion 30 may be performed by a laser dicing device. When the base material 10 is separated, the dicing step S10 is completed.

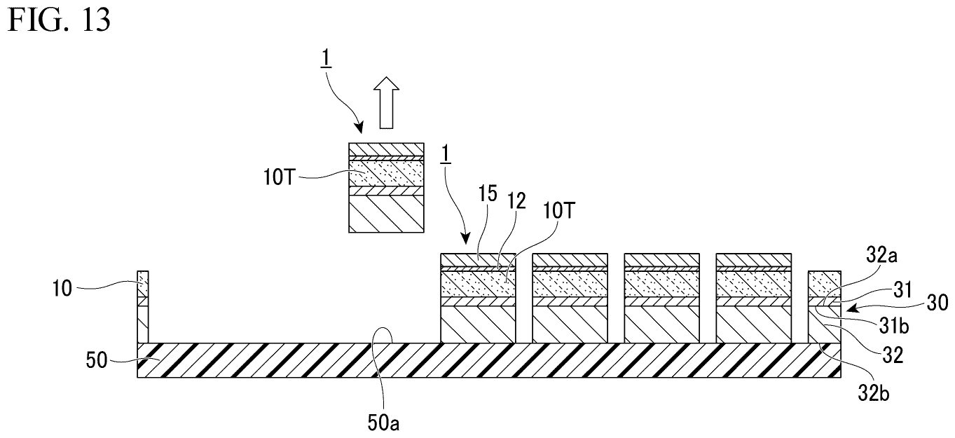

The pick-up step S11 is a step of separately removing the plurality of semiconductor devices 1 fixed to the dicing tape 50 from the dicing tape 50. As shown in FIG. 13, first, the operator or the like performs a treatment for weakening the adhesive strength of an adhesive layer (not shown) on a front surface 50a of the dicing tape 50. The operator or the like weakens the adhesive strength of the adhesive layer of the dicing tape 50 by performing a treatment such as irradiating the adhesive layer with ultraviolet light or heating the adhesive layer. Next, the operator or the like pushes one of the semiconductor devices 1 to the upper side from the lower side of the dicing tape 50 using a member such as a pin (not shown) and applies a negative pressure to the device surface 10a of the semiconductor device 1 using an extraction device (not shown) to adsorb the semiconductor device 1 to the extraction device, thereby separately removing the semiconductor device 1 from the dicing tape 50. When all the semiconductor devices 1 are removed from the dicing tape 50, the pick-up step S11 is completed. As shown in FIG. 2, when the pick-up step S11 is completed, the manufacturing process of the semiconductor device 1 is completed and a plurality of semiconductor devices 1 are manufactured.

According to the present embodiment, the method for manufacturing the semiconductor device 1 has the first film forming step S04 of forming the first electrode layer 31 on the base material back surface 10b of the base material 10, the second film forming step S05 of forming the second electrode layer 32 on the front surface 40a of the film-formed member 40, the joining step S06 of joining the first electrode layer 31 and the second electrode layer 32 to each other, and the film-formed member removing step S07 of removing the film-formed member 40 from the second electrode layer 32. Therefore, the back surface electrode portion 30 can be constituted by the first electrode layer 31 and the second electrode layer 32 joined to each other. For this reason, in this case, the thickness of the back surface electrode portion 30 can be made greater than that in the case in which the back surface electrode portion 30 is constituted by only one of the first electrode layer 31 and the second electrode layer 32. As a result, it is possible to reduce the thermal resistance of the back surface electrode portion 30, and thus it is possible to increase the heating value discharged from the circuit portion 12 to the outside of the semiconductor device 1 via the back surface electrode portion 30. Therefore, it is possible to prevent the temperature of the circuit portion 12 from becoming too high, and thus it is possible to improve the stability of the operation of the semiconductor device 1.

In addition, according to the present embodiment, as described above, it is possible to increase the thickness of the back surface electrode portion 30, and thus it is possible to increase the strength of the back surface electrode portion 30. For this reason, it is possible to increase the strength of the semiconductor device 1. As a result, it is possible to suppress that the semiconductor device 1 is damaged due to stress applied to the semiconductor device 1 when the semiconductor device 1 is removed from the dicing tape 50 in the pick-up step S11. Therefore, it is possible to increase the yield of the semiconductor device 1. In addition, as described above, it is possible to increase the strength of the semiconductor device 1, and thus it is possible to suppress that the semiconductor device 1 is damaged due to stress, such as thermal stress, applied to the semiconductor device 1 when the semiconductor device 1 is in use. Therefore, it is possible to improve the stability of the operation of the semiconductor device 1.

According to the present embodiment, in the first film forming step S04, the first electrode layer 31 is formed by the physical vapor deposition method, and in the second film forming step S05, the second electrode layer 32 is formed by the plating process. Therefore, in this case, since the second electrode layer 32 is formed by the plating process, the amount of the operation required to form the second electrode layer 32 to a thickness of, for example, 10 μm or more can be reduced compared to the case in which the second electrode layer 32 is formed by the physical vapor deposition method. Therefore, the amount of the operation required to form the back surface electrode portion 30 can be reduced compared to the case in which the entire back surface electrode portion 30 is formed by the physical vapor deposition method.

In addition, according to the present embodiment, in the second film forming step S05, the second electrode layer 32 is formed by performing the plating process on the film-formed member 40, which is a separate member from the base material 10. For this reason, it is possible to prevent a chemical liquid used in the plating process from adhering to the circuit portion 12 and the front surface electrode portion 15 formed on the device surface 10a of the base material 10. Therefore, it is possible to prevent the circuit portion 12 and the front surface electrode portion 15 from being deteriorated with the chemical liquid, and thus it is possible to suppress a decrease in the yield of the semiconductor device 1. In addition, it is possible to prevent the circuit portion 12 and the front surface electrode portion 15 from being deteriorated, and thus it is possible to improve the stability of the operation of the semiconductor device 1.

In addition, according to the present embodiment, as described above, in the second film forming step S05, the second electrode layer 32 is formed by performing the plating process on the film-formed member 40, which is a separate member from the base material 10, and thus it is possible to prevent the above-described chemical liquid from adhering to the adhesive 25. Therefore, it is possible to prevent the adhesive 25 from being deteriorated, and thus it is possible to suppress a decrease in the adhesive strength between the support substrate 20 and the base material 10. As a result, in each of the joining step S06, the film-formed member removing step S07, and the second attaching step S08, it is possible to stabilize the shape of the base material 10 in the vertical direction and the position of the base material 10 in the vertical direction. Therefore, as described above, it is possible to simplify the operation in each of the joining step S06, the film-formed member removing step S07, and the second attaching step S08, and thus it is possible to suppress an increase in the number of steps required for manufacturing the semiconductor substrate 1.

According to the present embodiment, the material constituting the first electrode layer 31 and the material constituting the second electrode layer 32 are the same material. Therefore, in this case, it is easier to increase the joining strength between the first electrode layer 31 and the second electrode layer 32 compared to the case in which the material constituting the first electrode layer 31 and the material constituting the second electrode layer 32 are different materials. As a result, it is possible to more suitably increase the strength of the back surface electrode portion 30, and thus it is possible to more suitably increase the strength of the semiconductor device 1. Therefore, it is possible to more suitably suppress that the semiconductor device 1 is damaged due to stress applied to the semiconductor device 1 when the semiconductor device 1 is removed from the dicing tape 50 in the pick-up step S11. Therefore, it is possible to more suitably increase the yield of the semiconductor device 1. In addition, it is possible to more suitably suppress that the semiconductor device 1 is damaged due to stress, such as thermal stress, applied to the semiconductor device 1 when the semiconductor device 1 is in use. Therefore, it is possible to more suitably improve the stability of the operation of the semiconductor device 1.

### Second Embodiment

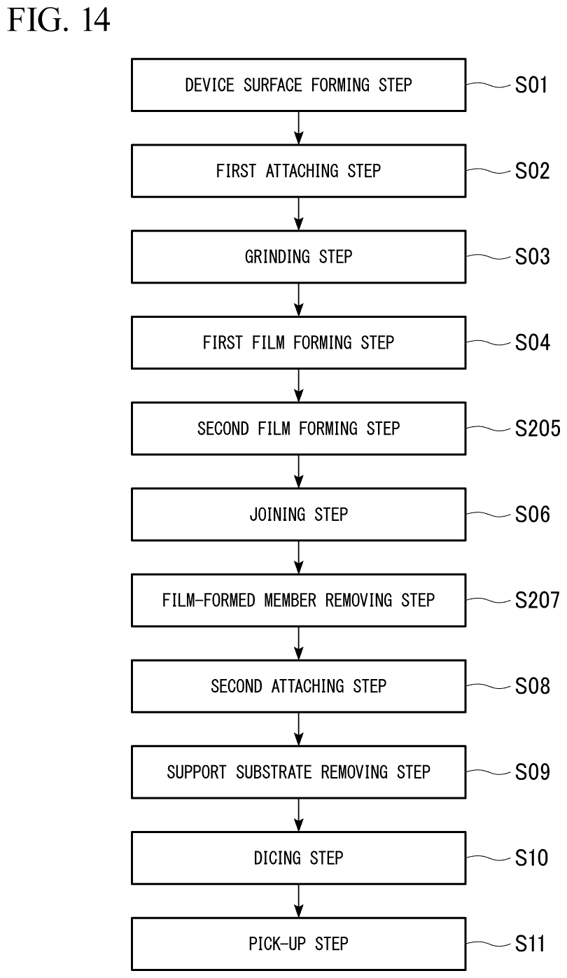

FIG. 14 is a flowchart showing a method for manufacturing a semiconductor device 1 according to the present embodiment. The method for manufacturing the semiconductor device 1 of the present embodiment has a device surface forming step S01, a first attaching step S02, a grinding step S03, a first film forming step S04, a second film forming step S205, a joining step S06, a film-formed member removing step S207, a second attaching step S08, a support substrate removing step S09, a dicing step S10, and a pick-up step S11. The operations performed in the second film forming step S205 and the film-formed member removing step S207 of the present embodiment are different from the operations performed in the second film forming step S05 and the film-formed member removing step S07 of the first embodiment described above. The operations of the other steps in the method for manufacturing the semiconductor device 1 of the present embodiment are similar to the operations of the other steps in the method for manufacturing the semiconductor device 1 of the first embodiment described above. In the following description, the same constituent elements in aspect as those in the first embodiment described above are designated by the same reference signs, and the description thereof will be omitted.

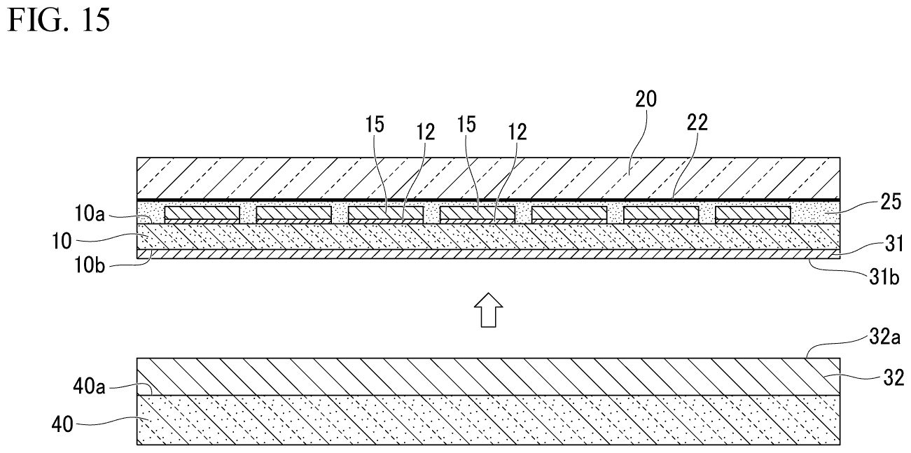

As shown in FIG. 15, the second film forming step S205 is a step of forming a second electrode layer 32 on a front surface 40a of a film-formed member 40. In the present embodiment, the second electrode layer 32 is formed directly on the front surface 40a of the film-formed member 40. The second electrode layer 32 is formed by a plating process. The thickness of the second electrode layer 32 is preferably in the range of 10 μm or more and 50 μm or less. In the present embodiment, the thickness of the second electrode layer 32 is about 20 μm. The thickness of the second electrode layer 32 is greater than the thickness of a first electrode layer 31. When the second electrode layer 32 is formed on the front surface 40a of the film-formed member 40, the second film forming step S205 is completed. Other configurations of the film-formed member 40 and the second electrode layer 32 of the present embodiment are similar to those of the film-formed member 40 and the second electrode layer 32 of the first embodiment described above.

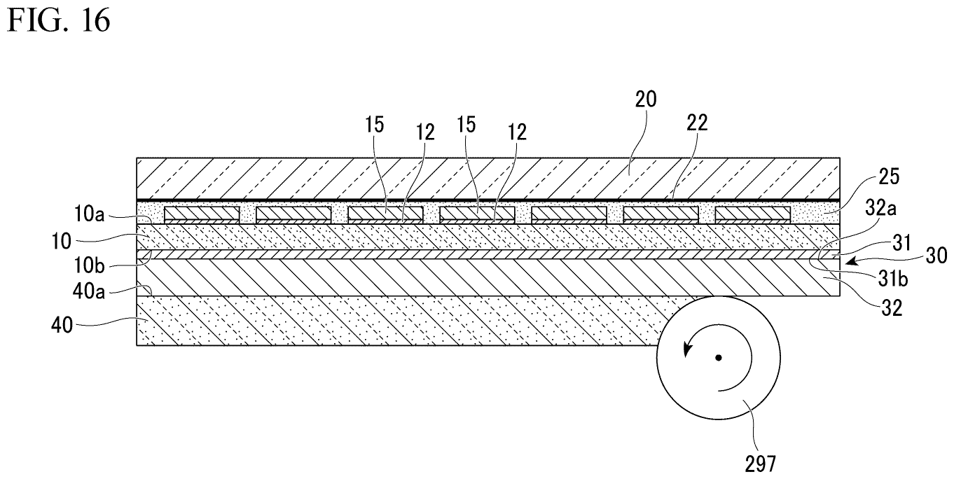

As shown in FIG. 16, the film-formed member removing step S207 is a step of removing the film-formed member 40 from the second electrode layer 32. In the present embodiment, the operator or the like grinds the film-formed member 40 using a grinding device 297 to remove the film-formed member 40 from the second electrode layer 32. In the present embodiment, the grinding device 297 is a surface grinding machine that grinds a grinding target object using a rotating disk-shaped grinding wheel. When the film-formed member 40 is removed from the second electrode layer 32, the film-formed member removing step S207 is completed.

According to the present embodiment, as shown in FIG. 16, a back surface electrode portion 30 can be constituted by the first electrode layer 31 and the second electrode layer 32 joined to each other. For this reason, similarly to the first embodiment described above, in this case, the thickness of the back surface electrode portion 30 can be made greater than that in the case in which the back surface electrode portion 30 is constituted by only one of the first electrode layer 31 and the second electrode layer 32. As a result, it is possible to reduce the thermal resistance of the back surface electrode portion 30, and thus it is possible to increase the heating value discharged from a circuit portion 12 to the outside of the semiconductor device 1 via the back surface electrode portion 30. Therefore, it is possible to prevent the temperature of the circuit portion 12 from becoming too high, and thus it is possible to improve the stability of the operation of the semiconductor device 1.

In addition, according to the present embodiment, as described above, it is possible to increase the thickness of the back surface electrode portion 30, and thus it is possible to increase the strength of the back surface electrode portion 30. For this reason, it is possible to increase the strength of the semiconductor device 1. As a result, it possible to suppress that the semiconductor device 1 is damaged in the pick-up step S11, similarly to the first embodiment described above. Therefore, it is possible to increase the yield of the semiconductor device 1. In addition, it is possible to more suitably suppress that the semiconductor device 1 is damaged when the semiconductor device 1 is in use. Therefore, it is possible to improve the stability of the operation of the semiconductor device 1.

According to at least one of the embodiments described above, the method for manufacturing the semiconductor device includes the first film forming step of forming the first electrode layer on the base material back surface facing a side opposite to a device surface of the base material, the second film forming step of forming the second electrode layer on the front surface of the film-formed member, the joining step of joining the first electrode layer and the second electrode layer to each other, and the film-formed member removing step of removing the film-formed member from the second electrode layer, and thus it is possible to provide a semiconductor device that can be stably operated.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising:
a first film forming step of forming a first electrode layer on a base material back surface facing a side opposite to a device surface of the base material on which a circuit portion is formed;
a second film forming step of forming a second electrode layer on a front surface of a film-formed member;
a joining step of joining the first electrode layer and the second electrode layer; and
a film-formed member removing step of removing the film-formed member from the second electrode layer.

2. The method for manufacturing a semiconductor device according to claim 1,
wherein, in the second film forming step, the second electrode layer is formed on the front surface of the film-formed member with an intermediate layer containing aluminum atoms interposed therebetween, and
wherein, in the film-formed member removing step, after at least the intermediate layer is immersed in water, the film-formed member is removed from the second electrode layer.

3. The method for manufacturing a semiconductor device according to claim 2,
wherein a temperature of the water is 50° C. or more and 100° C. or less.

4. The method for manufacturing a semiconductor device according to claim 1, wherein, in the first film forming step, the first electrode layer is formed by a physical vapor deposition method, and
wherein, in the second film forming step, the second electrode layer is formed by a plating process.

5. The method for manufacturing a semiconductor device according to claim 1,
wherein a material constituting the first electrode layer and a material constituting the second electrode layer are the same material.

6. The method for manufacturing a semiconductor device according to claim 1, further comprising a first attaching step of attaching a support substrate to the device surface of the base material with an adhesive prior to the first film forming step.

7. The method for manufacturing a semiconductor device according to claim 6, further comprising, after the film-formed member removing step:
a support substrate removing step of removing the support substrate from the base material; and
a dicing step of separating the base material.
